(19) United States
(12) Patent Application Publication
(10) Pub. No.: US 2017/0273201 A1
(43) Pub. Date: Sep. 21, 2017

(54) METHODS FOR PREPARING STRENGTHENED LITHIUM-BASED GLASS ARTICLES AND LITHIUM-BASED GLASS ARTICLES

(71) Applicant: Corning Incorporated, Corning, NY (US)

(72) Inventor: Kristen Lorraine Eckart, Corning, NY (US)

(21) Appl. No.: 15/461,788

(22) Filed: Mar. 17, 2017

Related U.S. Application Data
(60) Provisional application No. 62/310,272, filed on Mar. 18, 2016.

(51) Int. Cl. H05K 5/02; H05K 5/00; C03C 21/00; C03C 3/087; C03C 4/18

(52) U.S. Cl. CPC H05K 5/0217; C03C 3/087; C03C 4/18; C03C 21/002; H05K 5/0017; C03C 2204/00

(57) ABSTRACT

A method for strengthening a glass article and strengthened glass articles formed from the method are disclosed. The method includes contacting the glass article with an ion exchange solution for about 4 hours to about 8 hours. The ion exchange solution has a temperature from about 370° C. to about 410° C. The ion exchange solution includes about 65 mol. % to about 75 mol. % KNO₃ and from about 25 mol. % to about 35 mol. % NaNO₃ Prior to the contacting, the glass article has a composition of about 55 mol. % to about 75 mol. % SiO₂, about 8 mol. % to about 15 mol. % Al₂O₃, about 5 mol. % to about 12 mol. % Na₂O, about 8 mol. % to about 14 mol. % Li₂O; 0 mol. % to about 1 mol. % K₂O, 0 mol. % to about 2 mol. % MgO, 0 mol. % to about 2 mol. % CaO, and 0 mol. % to about 2 mol. % ZrO₂.

### CROSS-REFERENCE To RELATED APPLICATIONS

This application claims the benefit of priority of U.S. Provisional Application Ser. No. 62/310,272, filed Mar. 18, 2016, the contents of which are relied upon and incorporated herein by reference in their entirety.

### BACKGROUND

Field

The present specification generally relates to glass articles and, more specifically, to lithium-based glass articles that have been chemically strengthened and have high drop and abrasion resistance.

Technical Background

Glass articles are commonly utilized in a variety of consumer and commercial applications such as electronic applications, automotive applications, and even architectural applications. For example, consumer electronic devices, such as mobile phones, computer monitors, GPS devices, televisions, and the like, commonly incorporate glass articles as part of a display. In some of these devices, the glass article is also utilized to enable touch functionality, such as when the displays are touch screens. Many of these devices are portable and, as such, the glass articles incorporated in the devices need to be sufficiently robust to withstand impact and/or damage, such as cracks, scratches and the like, during both use and transport.

### SUMMARY

According to one embodiment, a method for strengthening a glass article comprises: contacting a glass article with an ion exchange solution for a duration of from greater than or equal to about 4 hours to less than or equal to about 8 hours, the ion exchange solution having a temperature from greater than or equal to about 370° C. to less than or equal to about 410° C. during the contacting; and separating the ion exchange solution from the glass article. The ion exchange solution comprises from greater than or equal to about 65 mol. % to less than or equal to about 75 mol. % KNO₃ and from greater than or equal to about 25 mol. % to less than or equal to about 35 mol. % NaNO₃. Prior to the contacting, the glass article comprises from greater than or equal to about 55 mol. % to less than or equal to about 75 mol. % SiO₂, greater than or equal to about 8 mol. % to less than or equal to about 15 mol. % Al₂O₃, greater than or equal to about 5 mol. % to less than or equal to about 12 mol. % Na₂O, greater than or equal to about 8 mol. % to less than or equal to about 14 mol. % Li₂O; greater than or equal to 0 mol. % to less than or equal to about 1 mol. % K₂O, greater than or equal to 0 mol. % to less than or equal to about 2 mol. % MgO, greater than or equal to 0 mol. % to less than or equal to about 2 mol. % CaO, and greater than or equal to 0 mol. % to less than or equal to about 2 mol. % ZrO₂.

According to another embodiment, a method for producing a strengthened glass article consists essentially of: contacting a glass article with an ion exchange solution for a duration of from greater than or equal to about 4 hours to less than or equal to about 8 hours, the ion exchange solution having a temperature from greater than or equal to about 370° C. to less than or equal to about 410° C. during the contacting; and separating the ion exchange solution from the glass article. The ion exchange solution comprises from greater than or equal to about 65 mol. % to less than or equal to about 75 mol. % KNO₃ and from greater than or equal to about 25 mol. % to less than or equal to about 35 mol. % NaNO₃. Prior to the contacting, the glass article comprises from greater than or equal to about 55 mol. % to less than or equal to about 75 mol. % SiO₂, greater than or equal to about 8 mol. % to less than or equal to about 15 mol. % Al₂O₃, greater than or equal to about 5 mol. % to less than or equal to about 12 mol. % Na₂O, greater than or equal to about 8 mol. % to less than or equal to about 14 mol. % Li₂O; greater than or equal to 0 mol. % to less than or equal to about 1 mol. % K₂O, greater than or equal to 0 mol. % to less than or equal to about 2 mol. % MgO, greater than or equal to 0 mol. % to less than or equal to about 2 mol. % CaO, and greater than or equal to 0 mol. % to less than or equal to about 2 mol. % ZrO₂.

According to an additional embodiment, a strengthened aluminosilicate glass article formed by a method comprising: contacting a precursor glass article and an ion exchange solution for a duration of from greater than or equal to about 4 hours to less than or equal to about 8 hours, the ion exchange solution having a temperature from greater than or equal to about 370° C. to less than or equal to about 410° C. during the contacting; and separating the ion exchange solution from the precursor glass article, yielding the strengthened aluminosilicate glass article. The ion exchange solution comprises from greater than or equal to about 65 mol. % to less than or equal to about 75 mol. % KNO₃ and from greater than or equal to about 25 mol. % to less than or equal to about 35 mol. % NaNO₃. The precursor glass article comprises from greater than or equal to about 55 mol. % to less than or equal to about 75 mol. % SiO₂, greater than or equal to about 8 mol. % to less than or equal to about 15 mol. % Al₂O₃, greater than or equal to about 5 mol. % to less than or equal to about 12 mol. % Na₂O, greater than or equal to about 8 mol. % to less than or equal to about 15 mol. % Li₂O; greater than or equal to 0 mol. % to less than or equal to about 2 mol. % K₂O, greater than or equal to 0 mol. % to less than or equal to about 2 mol. % MgO, greater than or equal to 0 mol. % to less than or equal to about 2 mol. % CaO, and greater than or equal to 0 mol. % to less than or equal to about 2 mol. % ZrO₂. The strengthened aluminosilicate glass article survives a drop test from a height of greater than or equal to about 190 cm.

In aspect (1) of the disclosure, a method for strengthening a glass article comprising is provided. The method comprising: contacting a glass article with an ion exchange solution for a duration of from greater than or equal to about 4 hours to less than or equal to about 8 hours, the ion exchange solution having a temperature from greater than or equal to about 370° C. to less than or equal to about 410° C. during the contacting; and separating the ion exchange solution from the glass article, wherein: the ion exchange solution comprises: from greater than or equal to about 65 mol. % to less than or equal to about 75 mol. % KNO₃, and from greater than or equal to about 25 mol. % to less than or equal to about 35 mol. % NaNO₃, and prior to the contacting, the glass article comprises: greater than or equal to about 55 mol. % to less than or equal to about 75 mol. % SiO₂, greater than or equal to about 8 mol. % to less than or equal to about 15 mol. % Al₂O₃, greater than or equal to about 5 mol. % to less than or equal to about 12 mol. % Na₂O, greater than or equal to about 8 mol. % to less than or equal to about 14 mol. % Li₂O, greater than or equal to 0 mol. % to less than or equal to about 1 mol. % K₂O, greater than or equal to 0 mol. % to less than or equal to about 2 mol. % MgO, greater than or equal to 0 mol. % to less than or equal to about 2 mol. % CaO, and greater than or equal to 0 mol. % to less than or equal to about 2 mol. % ZrO₂.

In aspect (2) of the disclosure, the method for strengthening a glass article of aspect (1) is provided, wherein a thickness of the glass article is less than or equal to about 1 mm.

In aspect (3) of the disclosure, the method for strengthening a glass article of aspect (1) or (2) is provided, wherein a thickness of the glass article is from greater than or equal to about 0.45 mm to less than or equal to about 0.85 mm.

In aspect (4) of the disclosure, the method for strengthening a glass article of any of aspects (1) to (3) is provided, wherein the duration of the contacting is from greater than or equal to about 5 hours to less than or equal to about 7 hours.

In aspect (5) of the disclosure, the method for strengthening a glass article of any of aspects (1) to (4) is provided, wherein the ion exchange solution has a temperature from greater than or equal to about 380° C. to less than or equal to about 400° C. during the contacting.

In aspect (6) of the disclosure, the method for strengthening a glass article of any of aspects (1) to (5) is provided, wherein the ion exchange solution comprises: from greater than or equal to about 68 mol. % to less than or equal to about 72 mol. % KNO₃, and from greater than or equal to about 28 mol. % to less than or equal to about 32 mol. %NaNO₃.

In aspect (7) of the disclosure, the method for strengthening a glass article of any of aspects (1) to (6) is provided, wherein the ion exchange solution comprises about 70 mol. % KNO₃ and about 30 mol. % NaNO₃.

In aspect (8) of the disclosure, the method for strengthening a glass article of any of aspects (1) to (7), wherein the glass article comprises: greater than or equal to about 62 mol. % to less than or equal to about 68 mol. % SiO₂, greater than or equal to about 10 mol. % to less than or equal to about 13 mol. % Al₂O₃, greater than or equal to about 7 mol. % to less than or equal to about 10 mol. % Na₂O, greater than or equal to about 9 mol. % to less than or equal to about 13 mol. % Li₂O, greater than or equal to 0.01 mol. % to less than or equal to about 0.07 mol. % K₂O, greater than or equal to 0.01 mol. % to less than or equal to about 0.5 mol. % MgO, and greater than or equal to 0 mol. % to less than or equal to about 1 mol. % CaO.

In aspect (9) of the disclosure, a method for producing a strengthened glass article is provided. The method consisting essentially of: contacting a glass article with an ion exchange solution for a duration of from greater than or equal to about 4 hours to less than or equal to about 8 hours, the ion exchange solution having a temperature from greater than or equal to about 370° C. to less than or equal to about 410° C. during the contacting; and separating the ion exchange solution from the glass article, wherein: the ion exchange solution consists essentially of: from greater than or equal to about 65 mol. % to less than or equal to about 75 mol. % KNO₃, and from greater than or equal to about 25 mol. % to less than or equal to about 35 mol. % NaNO₃, and prior to the contacting, the glass article consists essentially of: greater than or equal to about 55 mol. % to less than or equal to about 75 mol. % SiO₂, greater than or equal to about 8 mol. % to less than or equal to about 15 mol. % Al₂O₃, greater than or equal to about 5 mol. % to less than or equal to about 12 mol. % Na₂O, greater than or equal to about 8 mol. % to less than or equal to about 14 mol. % Li₂O, greater than or equal to 0 mol. % to less than or equal to about 1 mol. % K₂O, greater than or equal to 0 mol. % to less than or equal to about 2 mol. % MgO, greater than or equal to 0 mol. % to less than or equal to about 2 mol. % CaO, and greater than or equal to 0 mol. % to less than or equal to about 2 mol. % ZrO₂.

In aspect (10) of the disclosure, the method for producing a strengthened glass article of aspect (9) is provided, wherein the ion exchange solution consists essentially of: from greater than or equal to about 68 mol. % to less than or equal to about 72 mol. % KNO₃, and from greater than or equal to about 28 mol. % to less than or equal to about 32 mol. % NaNO₃.

In aspect (11) of the disclosure, the method for producing a strengthened glass article of aspect (9) or (10) is provided, wherein the glass article consists essentially of: greater than or equal to about 62 mol. % to less than or equal to about 68 mol. % SiO₂, greater than or equal to about 10 mol. % to less than or equal to about 13 mol. % Al₂O₃, greater than or equal to about 7 mol. % to less than or equal to about 10 mol. % Na₂O, greater than or equal to about 9 mol. % to less than or equal to about 13 mol. % Li₂O, greater than or equal to 0.01 mol. % to less than or equal to about 0.07 mol. % K₂O, greater than or equal to 0.01 mol. % to less than or equal to about 0.05 mol. % MgO, and greater than or equal to 0.2 mol. % to less than or equal to about 1 mol. % CaO.

In aspect (12) of the disclosure, the method for producing a strengthened glass article of any of aspects (9) to (11), wherein the ion exchange solution has a temperature from greater than or equal to about 380° C. to less than or equal to about 400° C. during the contacting.

In aspect (13) of the disclosure, a strengthened aluminosilicate glass article is provided. The strengthened aluminosilicate glass article is formed by a method comprising: contacting a precursor glass article and an ion exchange solution for a duration of from greater than or equal to about 4 hours to less than or equal to about 8 hours, the ion exchange solution having a temperature from greater than or equal to about 370° C. to less than or equal to about 410° C. during the contacting; and separating the ion exchange solution from the precursor glass article, yielding the strengthened aluminosilicate glass article, wherein: the ion exchange solution comprises: from greater than or equal to about 65 mol. % to less than or equal to about 75 mol. % KNO₃, and from greater than or equal to about 25 mol. % to less than or equal to about 35 mol. % NaNO₃, the precursor glass article comprises: greater than or equal to about 55 mol. % to less than or equal to about 75 mol. % SiO₂, greater than or equal to about 8 mol. % to less than or equal to about 15 mol. % Al₂O₃, greater than or equal to about 5 mol. % to less than or equal to about 12 mol. % Na₂O, greater than or equal to about 8 mol. % to less than or equal to about 15 mol. % Li₂O, greater than or equal to 0 mol. % to less than or equal to about 2 mol. % K₂O, greater than or equal to 0 mol. % to less than or equal to about 2 mol. % MgO, greater than or equal to 0 mol. % to less than or equal to about 2 mol. % CaO, and greater than or equal to 0 mol. % to less than or equal to about 2 mol. % ZrO₂, and the strengthened aluminosilicate glass article survives a drop test from a height of greater than or equal to about 190 cm.

In aspect (14) of the disclosure, the strengthened aluminosilicate glass article of aspect (13) is provided, wherein the precursor glass article comprises: greater than or equal to about 62 mol. % to less than or equal to about 68 mol. % SiO₂, greater than or equal to about 10 mol. % to less than or equal to about 13 mol. % Al₂O₃, greater than or equal to about 7 mol. % to less than or equal to about 11 mol. % Na₂O, greater than or equal to about 9 mol. % to less than or equal to about 12 mol. % Li₂O, greater than or equal to 0 mol. % to less than or equal to about 1 mol. % K₂O, greater than or equal to 0 mol. % to less than or equal to about 1 mol. % MgO, and greater than or equal to 0 mol. % to less than or equal to about 1 mol. % CaO.

In aspect (15) of the disclosure, the strengthened aluminosilicate glass article of aspect (13) or (14), wherein the strengthened aluminosilicate glass article survives a drop test from a height of greater than or equal to about 200 cm.

In aspect (16) of the disclosure, the strengthened aluminosilicate glass article of any of aspects (13) to (15), wherein the strengthened aluminosilicate glass article survives a drop test from a height of greater than or equal to about 220 cm.

In aspect (17) of the disclosure, the strengthened aluminosilicate glass article of any of aspects (13) to (16), wherein the strengthened aluminosilicate glass article has a thickness less than or equal to about 0.8 mm, and an abrasion resistance of greater than or equal to about 35 kgf.

In aspect (18) of the disclosure, the strengthened aluminosilicate glass article of any of aspects (13) to (17), wherein the strengthened aluminosilicate glass article has a thickness less than or equal to about 0.55 mm, and an abrasion resistance of greater than or equal to about 15 kgf.

In aspect (19) of the disclosure, the strengthened aluminosilicate glass article of any of aspects (13) to (18), wherein the ion exchange solution comprises: from greater than or equal to about 68 mol. % to less than or equal to about 72 mol. % KNO₃, and from greater than or equal to about 28 mol. % to less than or equal to about 32 mol. % NaNO₃.

In aspect (20) of the disclosure, the strengthened aluminosilicate glass article of any of aspects (13) to (19), wherein the ion exchange solution has a temperature from greater than or equal to about 380° C. to less than or equal to about 400° C. during the contacting.

In aspect (21) of the disclosure, a consumer electronic product is provided. The consumer electronic product comprises: a housing having a front surface, a back surface and side surfaces; electrical components provided at least partially within the housing, the electrical components including at least a controller, a memory, and a display, the display being provided at or adjacent the front surface of the housing; and a cover glass disposed over the display, wherein at least one of a portion of the housing or the cover glass comprises the strengthened aluminosilicate glass article of any of aspects (13) to (20).

Additional features and advantages will be set forth in the detailed description which follows, and in part will be readily apparent to those skilled in the art from that description or recognized by practicing the embodiments described herein, including the detailed description which follows, the claims, as well as the appended drawings.

It is to be understood that both the foregoing general description and the following detailed description describe various embodiments and are intended to provide an overview or framework for understanding the nature and character of the claimed subject matter. The accompanying drawings are included to provide a further understanding of the various embodiments, and are incorporated into and constitute a part of this specification. The drawings illustrate the various embodiments described herein, and together with the description serve to explain the principles and operations of the claimed subject matter.

### BRIEF DESCRIPTION OF THE DRAWING

FIG. 1 schematically depicts a strengthened glass article according to embodiments disclosed herein;

FIG. 2 is a schematic cross-section view of an abraded ring-on-ring test apparatus;

FIG. 3A is a plan view of an exemplary electronic device incorporating any of the strengthened articles disclosed herein; and

FIG. 3B is a perspective view of the exemplary electronic device of FIG. 3A.

### DETAILED DESCRIPTION

Methods for strengthening glass articles are disclosed herein. Some embodiments of the methods comprise contacting a glass article with an ion exchange solution for a duration of from greater than or equal to about 4 hours to less than or equal to about 8 hours, the ion exchange solution has a temperature from greater than or equal to about 370° C. to less than or equal to about 410° C. during the contacting. After the contacting, the ion exchange solution and the glass article are separated. In some embodiments, the ion exchange solution comprises from greater than or equal to about 65 mol. % to less than or equal to about 75 mol. % KNO₃ and from greater than or equal to about 25 mol. % to less than or equal to about 35 mol. % NaNO₃. In some embodiments, the glass article comprises—prior to the contacting—from greater than or equal to about 55 mol. % to less than or equal to about 75 mol. % SiO₂, greater than or equal to about 8 mol. % to less than or equal to about 15 mol. % Al₂O₃, greater than or equal to about 5 mol. % to less than or equal to about 12 mol. % Na₂O, greater than or equal to about 8 mol. % to less than or equal to about 14 mol. % Li₂O; greater than or equal to 0 mol. % to less than or equal to about 1 mol. % K₂O, greater than or equal to 0 mol. % to less than or equal to about 2 mol. % MgO, greater than or equal to 0 mol. % to less than or equal to about 2 mol. % CaO, and greater than or equal to 0 mol. % to less than or equal to about 2 mol. % ZrO₂.

The glass composition according to some embodiments is a lithium aluminosilicate glass. The composition of the glass article prior to the contacting with the ion exchange solution is described below by its individual components. Although specific glass compositions and ranges of constituents of the glass composition are provided separately below, it should be understood that the various constituents of the glass compositions may be combined without limitation and that all possible combinations of constituents are envisioned in embodiments of this disclosure.

In some embodiments, SiO₂ is the largest constituent of the glass composition and, as such, SiO₂ is the primary constituent of the glass network formed from the glass composition. Pure SiO₂ has a relatively low coefficient of thermal expansion (CTE). However, pure SiO₂ has a high melting point. Accordingly, if the concentration of SiO₂ in the glass composition is too high, the formability of the glass composition can be diminished as higher concentrations of SiO₂ increase the difficulty of melting the glass, which, in turn, adversely impacts the formability of the glass. Low SiO₂ glasses, such as, for example, a glass with less than 50 mol. % SiO₂, tend to have poor durability and resistance to devitrification, so it is practical to have more than 55 mol. % SiO₂ for ease of forming.

In some embodiments, the glass composition comprises SiO₂ in a concentration from greater than or equal to about 55 mol. % to less than or equal to about 75 mol. %, such as greater than or equal to about 60 mol. % to less than or equal to about 70 mol. %, greater than or equal to about 62 mol. % to less than or equal to about 68 mol. %, greater than or equal to about 64 mol. % to less than or equal to about 66 mol. %, about 65 mol. % SiO₂, or any sub-ranges contained therein.

The glass composition of some embodiments further comprises Al₂O₃ in addition to SiO₂. Al₂O₃ serves as a glass network former, similar to SiO₂. Al₂O₃ increases the viscosity of the glass composition. However, when the concentration of Al₂O₃ is balanced against the concentration of SiO₂ and, optionally, the concentration of alkali oxides in the glass composition, Al₂O₃ can reduce the liquidus temperature of the glass melt, thereby enhancing the liquidus viscosity and improving the compatibility of the glass composition with certain forming processes, such as, for example, down-draw processes and the like. In addition, Al₂O₃ enhances the ion exchange performance of alkali silicate glasses.

In some embodiments, the glass composition comprises Al₂O₃ in a concentration from greater than or equal to about 8 mol. % to less than or equal to about 15 mol. %, such as greater than or equal to about 9 mol. % to less than or equal to about 14 mol. %, greater than or equal to about 10 mol. % to less than or equal to about 13 mol. %, greater than or equal to about 11 mol. % to less than or equal to about 12 mol. %, or any sub-ranges contained therein.

Alkali metal oxides (hereinafter referred to as “R₂O” where “R” is one or more alkali metals) may be added to the glass composition to lower the viscosity of a glass and improve the meltability and the formability thereof. In addition, alkali metal oxides also enable ion exchange that modifies both the stress and refractive index profiles of the glass. When the content of R₂O is too large, the coefficient of thermal expansion of the glass becomes too large, and the thermal shock resistance of the glass may decrease. The glass compositions disclosed herein comprise Li₂O as an alkali metal oxide. In some embodiments, the glass composition comprises one or more of Na₂O, K₂O, Rb₂O, and Cs₂O as an alkali metal oxide in addition to Li₂O.

In some embodiments, the composition comprises Li₂O in a concentration from greater than or equal to about 8 mol. % to less than or equal to about 14 mol. %, such as greater than or equal to about 9 mol. % to less than or equal to about 13 mol. %, greater than or equal to about 10 mol. % to less than or equal to about 12 mol. %, greater than or equal to about 10 mol. % to less than or equal to about 11 mol. %, or any sub-ranges contained therein.

In some embodiments, the composition comprises Na₂O in a concentration from greater than or equal to about 5 mol. % to less than or equal to about 12 mol. %, such as greater than or equal to about 6 mol. % to less than or equal to about 11 mol. %, greater than or equal to about 7 mol. % to less than or equal to about 10 mol. %, greater than or equal to about 8 mol. % to less than or equal to about 10 mol. %, or any sub-ranges contained therein.

In some embodiments, the composition comprises K₂O in a concentration from greater than or equal to about 0 mol. % to less than or equal to about 1 mol. %, such as greater than or equal to about 0.01 mol. % to less than or equal to about 0.5 mol. %, greater than or equal to about 0.01 mol. % to less than or equal to about 0.07 mol. %, or any sub-ranges contained therein.

In some embodiments, the glass composition comprises R₂O in a total concentration from greater than or equal to about 14 mol. % to less than or equal to about 22 mol. %, such as greater than or equal to about 15 mol. % to less than or equal to about 20 mol. %, greater than or equal to about 16 mol. % to less than or equal to about 19 mol. %, greater than or equal to about 17 mol. % to less than or equal to about 18 mol. %, or any sub-ranges contained therein.

Including a relatively high amount of R₂O in the glass composition allows enhanced ionic interdiffusion of small alkali metal ions and large alkali metal ions during ion exchange processes (e.g., ion exchange in a molten KNO₃ and/or NaNO₃ salt bath at about 400° C.). Without being constrained to any particular theory, the relatively high amount of R₂O may act as a charge compensator for Al³⁺, thereby forming charge balanced units tetrahedrally coordinated with oxygen. This tetrahedral coordination allows for stronger glass articles.

To retain high indentation damage resistance, glass compositions according to some embodiments have a molar ratio of Al₂O₃ to R₂O of from greater than or equal to about 0.5:1 to less than or equal to about 1.0:1.0, such as greater than or equal to about 0.75:1.0 to less than or equal to about 1.0:1.0, or any sub-ranges contained therein. In some embodiments, the glass composition has a molar ratio of Al₂O₃ to Li₂O of greater than or equal to about 0.8:1.0 to less than or equal to about 1.2:1.0, such as greater than or equal to about 0.9:1.0 to less than or equal to about 1.1:1.0, or any sub-ranges contained therein.

The glass composition can—in some embodiments—contain other elements, such as alkaline earth metal oxides. In some embodiments, the alkaline earth metal oxides can be selected from MgO, CaO, SrO, BaO, and combinations thereof. These oxides can be added to increase the meltability, durability, and stability of the glass. In addition, alkaline earth metal oxides can be added as stabilizers that help prevent degradation of the glass composition upon exposure to environmental conditions. However, adding too much alkaline earth metal oxide to the glass composition can decrease its formability.

In some embodiments, the glass composition comprises alkaline earth metal oxides in concentrations from greater than or equal to 0 mol. % to less than or equal to about 3.0 mol. %, such as greater than or equal to about 0.5 mol. % to less than or equal to about 2.5 mol. %, greater than or equal to about 1.0 mol. % to less than or equal to about 2.0 mol. %, or any sub-ranges contained therein. In some embodiments, the glass composition comprises CaO in concentrations from greater than or equal to about 0 mol. % to less than or equal to about 2.0 mol. %, such as greater than or equal to about 0.2 mol. % to less than or equal to about 1.0 mol. %, or any sub-ranges contained therein. In some embodiments, the glass composition comprises MgO in concentrations from greater than or equal to about 0 mol. % to less than or equal to about 2.0 mol. %, such as greater than or equal to about 0.01 mol. % to less than or equal to about 0.5 mol. %, or any sub-ranges contained therein.

Embodiments of the glass composition can include ZrO₂, which can increase the chemical durability of the glass composition. In addition, ZrO₂ can also increase the glass transition temperature and decrease the coefficient of thermal expansion of the glass composition. However, a large amount of ZrO₂ can decrease the formability of the glass composition. In some embodiments, the glass composition comprises ZrO₂ in concentrations from greater than or equal to about 0 mol. % to less than or equal to about 2 mol. %, such as greater than or equal to about 0.5 mol. % to less than or equal to about 1.8 mol. %, greater than or equal to about 0.8 mol. % to less than or equal to about 1.5 mol. %, or any sub-ranges contained therein.

In some embodiments, the glass composition can comprise fining agents, such as, for example, SnO₂, sulfates, chlorides, bromides, Sb₂O₃, As₂O₃, SrO, TiO₂, Fe₂O₃, and Ce₂O₃. In some embodiments, the glass composition comprises one or more fining agents in concentrations from greater than or equal to 0 mol. % to less than or equal to about 1.0 mol. %, such as greater than or equal to about 0.002 mol. % to less than or equal to about 0.9 mol. %, greater than or equal to about 0.05 mol. % to less than or equal to about 0.8 mol. %, greater than or equal to about 0.1 mol. % to less than or equal to about 0.7 mol. %, greater than or equal to about 0.1 mol. % to less than or equal to about 0.3 mol. %, about 0.15 mol. %, or any sub-ranges contained therein. In embodiments that employ sulfates as a fining agent, the sulfates can be included in an amount from greater than or equal to about 0.001 mol. % to less than or equal to about 0.1 mol. %.

In some embodiments, the glass composition comprises SnO₂ in concentrations from greater than or equal to about 0 mol. % to less than or equal to about 0.01 mol. %, such as from greater than or equal to about 0 mol. % to less than or equal to about 0.001 mol. %, or any sub-ranges contained therein. In some other embodiments, the glass composition comprises TiO₂ in concentrations from greater than or equal to about 0 mol. % to less than or equal to about 0.1 mol. %, such as from greater than or equal to about 0.01 mol. % to less than or equal to about 0.05 mol. %, or any sub-ranges contained therein. In some embodiments, the glass composition comprises SrO in concentrations from greater than or equal to about 0 mol. % SrO to less than or equal to about 0.1 mol. %, such as from greater than or equal to about 0.001 mol. % to less than or equal to about 0.05 mol. %, or any sub-ranges contained therein. In some embodiments, the glass composition comprises Fe₂O₃ in concentrations from greater than or equal to about 0 mol. % to less than or equal to about 0.1 mol. %, such as from greater than or equal to about 0.01 mol. % to less than or equal to about 0.05 mol. %, or any sub-ranges contained therein

Glasses according to embodiments disclosed herein may be formed into glass articles, such as, for example, glass sheets. In some embodiments, the glass composition has a liquidus viscosity of at least 130 kilopoise and is down-drawable by suitable forming techniques, for example, but not limited to, fusion-draw processes, slot-draw processes, and re-draw processes. In other embodiments, the glass sheet can be made by the float process.

The glass composition may be formed into glass articles, such as, for example glass sheets, having any appropriate thickness. For example, for glass articles used in electronic devices such as touch screens or a touch screen cover glasses for cell phones, computers (including laptops and tablets) and ATMs, the glass article may have a thickness of less than or equal to about 1 mm. In some embodiments, the glass article has a thickness in the range of greater than or equal to about 0.2 mm to less than or equal to about 1 mm, such as greater than or equal to about 0.4 mm to less than or equal to about 1 mm, greater than or equal to about 0.45 mm to less than or equal to about 0.85 mm, or any sub-ranges contained therein.

According to some embodiments, the glass articles are chemically strengthened, such as, for example, by ion exchange. Glass compositions that are amenable to ion exchange typically contain smaller monovalent alkali metal ions, such as, for example, Li ions, that can be exchanged by larger monovalent alkali metal ions, such as, for example, Na, K, Rb, or Cs ions. In some embodiments, the glass composition initially comprises Li ions that are replaced by Na ions during an ion exchange process. Exemplary glass compositions that are amenable to this type of ion exchange are discussed above.

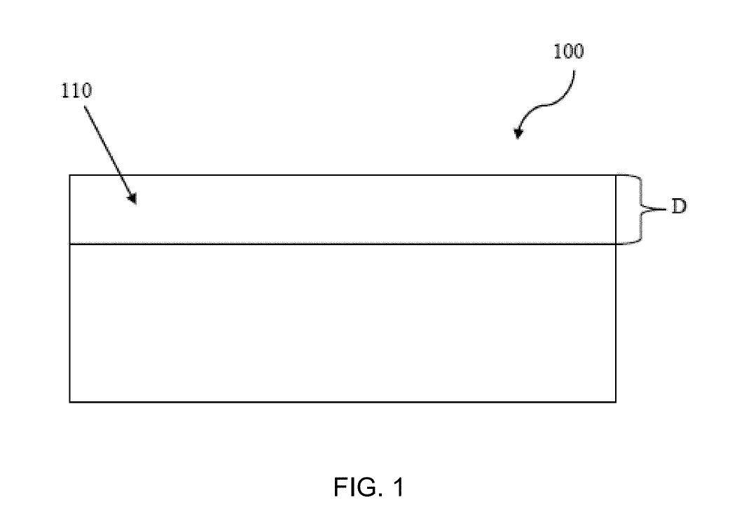

The ion exchange process includes contacting the glass article with an ion exchange solution. The glass article may be contacted with the ion exchange solution by spraying, immersing, coating, or other deposition technique. In some embodiments, the ion exchange process comprises immersing the glass article into a molten bath of the ion exchange solution. The ion exchange conditions are selected to enhance replacement of the smaller ions (such as Li ions) in the matrix of the glass article with larger ions present in the ion exchange solution (such as Na ions or K ions). With reference to FIG. 1, the ion exchange process described above forms a compressive stress layer 110 at the surface of the glass article 100 that is contacted with the ion exchange solution. Although FIG. 1 only shows one surface having a compressive stress layer 110, it should be understood that a compressive stress layer 110 may be formed on multiple surfaces of the glass article 100. The compressive stress layer 110 has at least two measurable parameters that contribute to the strength of the glass article: depth of layer ((DOL), which is represented by “D” in FIG. 1), and compressive stress (CS).

The duration of the contact between the glass article and the ion exchange solution is selected to enhance the exchange of smaller ions in the glass matrix with larger ions in the ion exchange solution. In some embodiments, the glass article is contacted with the ion exchange solution for a duration of from greater than or equal to about 4 hours to less than or equal to about 8 hours, such as greater than or equal to about 5 hours to less than or equal to about 7 hours, greater than or equal to about 5.5 hours to less than or equal to about 6.5 hours, or any sub-ranges contained therein.

The temperature of the ion exchange solution during the contacting of the glass article with the ion exchange solution is selected to enhance the exchange of smaller ions in the glass article with larger ions in the ion exchange solution. In some embodiments, the temperature of the ion exchange solution during the contacting of the glass article with the ion exchange solution is from greater than or equal to about 370° C. to less than or equal to about 410° C., such as greater than or equal to about 380° C. to less than or equal to about 400° C., greater than or equal to about 385° C. to less than or equal to about 395° C., about 390° C., or any sub-ranges contained therein.

The composition of the ion exchange solution aids the effectiveness of the ion exchange process, thereby improving the properties of the glass article. For example, and without being bound by any particular theory, glass compositions containing lithium can undergo an ion exchange process that yields a deep DOL by undergoing a two-step process where the glass article is first contacted to a molten bath of 100% NaNO₃ followed by contacting the glass article to a molten bath of 100% KNO₃. Also, a one-step ion exchange process comprising contacting a glass article with a molten bath comprising 95% KNO₃ and 5% NaNO₃ will yield a glass article with a deep depth of layer. However, a deep depth of layer alone does not ensure good abrasion resistance and strength. By contrast, using an ion exchange solution with a specific composition for the durations and at the temperatures disclosed herein provides the glass article with both good abrasion resistance and good strength.

In some embodiments, the ion exchange solution comprises a mixture of NaNO₃ and KNO₃. In some embodiments, the ion exchange solution comprises KNO₃ in a concentration from greater than or equal to about 65 mol. % to less than or equal to about 75 mol. % and comprises NaNO₃ in a concentration from greater than or equal to about 25 mol. % to less than or equal to about 35 mol. %. In some other embodiments, the ion exchange solution comprises KNO₃ in a concentration from greater than or equal to about 68 mol. % to less than or equal to about 72 mol. % and comprises NaNO₃ in a concentration from greater than or equal to about 28 mol. % to less than or equal to about 32 mol. %. In yet some other embodiments, the ion exchange solution comprises KNO₃ in a concentration of about 70 mol. % and comprises NaNO₃ in a concentration of about 30 mol. %.

Using glass compositions and an ion exchange conditions as disclosed herein provides a high-strength glass article having good abrasion resistance. The strength and abrasion resistance of strengthened glass articles formed according to embodiments disclosed herein are measured by the drop and abrasion tests described below.

As used in this disclosure, the strength of a glass article is measured by a two step drop test. For the drop test, a glass article is cut and the cut edges are finished—such as by grinding, polishing, etching, etc.—so that the cut glass article is of a size that can be placed into a handheld device (such as a cell phone) from which the original cover glass has been removed. After cutting and edge finishing, the glass article undergoes an ion exchange process. Once the ion exchange process is complete, the strengthened glass articles are washed, dried, and secured into the handheld devices to form a test device. The first step of the two-step drop test includes placing the test device in a first orientation and dropping the test device at the first orientation from a height of 1 meter onto a smooth piece of granite. If the glass article in the test device cracks upon being dropped, it is rejected and testing does not continue. But if the glass article in the test device does not crack, the non-cracked test device is then placed in a second orientation and dropped from 1 meter onto the smooth piece of granite. This process is repeated for 18 different orientations. Test devices that have not cracked after being dropped at all 18 orientations are then passed to the second step of the two-step drop test.

The second step of the drop test is only conducted on test devices that did not crack during the first step of the drop test. In the second step of the drop test, the test devices are dropped from various heights onto 180 grit sandpaper. The test devices are oriented so that the glass article is the first portion of the test device to contact the sandpaper. The test devices are dropped from heights of 22 cm, 30 cm, 40 cm, 50 cm, 60 cm, 70 cm, 80 cm, 90 cm, 100 cm, 110 cm, 120 cm, 130 cm, 140 cm, 150 cm, 160 cm, 170 cm, 180 cm, 190 cm, 200 cm, 210 cm, and 221 cm. The height at which the glass article cracks is then recorded as the drop height for that test device. However, if the glass article in the test device does not crack when dropped at a certain height, the glass article is said to have “survived” the drop test at that height. As an example, a glass article in a test device that does not crack when dropped at 130 cm, but cracks when dropped at 140 cm can be described as surviving a drop test at 130 cm and having a failure height of 140 cm.

In some embodiments, the glass article survives a drop test from heights of greater than or equal to about 190 cm, such as greater than or equal to about 200 cm, greater than or equal to about 210 cm, greater than or equal to about 221 cm, or more.

Abrasion resistance as discussed herein is measured using abraded ring on ring (AROR) testing. The strength of a material is defined as the stress at which fracture occurs. The AROR test is a surface strength measurement for testing flat glass specimens, and ASTM C1499-09(2013), entitled “Standard Test Method for Monotonic Equibiaxial Flexural Strength of Advanced Ceramics at Ambient Temperature,” serves as the basis for the AROR test methodology described herein. The contents of ASTM C1499-09 are incorporated herein by reference in their entirety. The glass specimen is abraded prior to ring-on-ring testing with 90 grit silicon carbide (SiC) particles that are delivered to the glass sample using the method and apparatus described in Annex A2, entitled “abrasion Procedures,” of ASTM C158-02(2012), entitled “Standard Test Methods for Strength of Glass by Flexure (Determination of Modulus of Rupture). The contents of ASTM C158-02 and the contents of Annex 2 in particular are incorporated herein by reference in their entirety.

Prior to ring-on-ring testing a surface of the glass-based article is abraded as described in ASTM C158-02, Annex 2, to normalize and/or control the surface defect condition of the sample using the apparatus shown in Figure A2.1 of ASTM C158-02. The abrasive material is sandblasted onto the surface of the glass-based article at a load of 104 Kilopascals (kPa) (15 pounds force per square inch (psi)) using an air pressure of 304 kPa (44 psi). After air flow is established, 5 cm³ of abrasive material is dumped into a funnel and the sample is sandblasted for 5 seconds after introduction of the abrasive material.

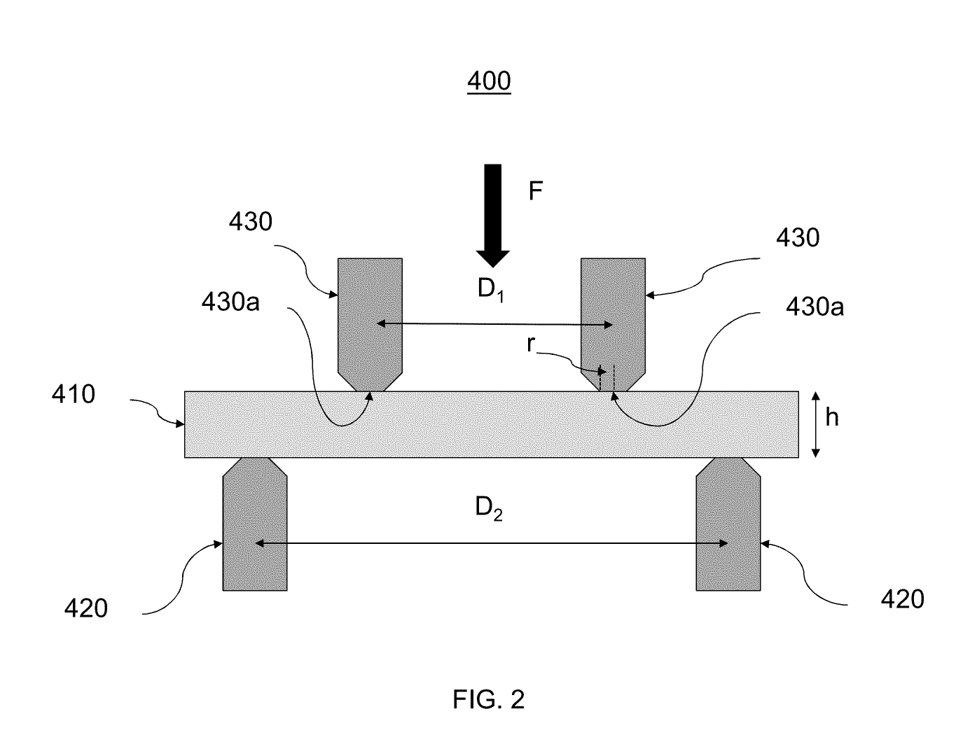

For the AROR test, a glass-based article having at least one abraded surface as shown in FIG. 2 is placed between two concentric rings of differing size to determine equibiaxial flexural strength (i.e., the maximum stress that a material is capable of sustaining when subjected to flexure between two concentric rings). In the AROR configuration 400, the abraded glass-based article 410 is supported by a support ring 420 having a diameter D2. A force F is applied by a load cell (not shown) to the surface of the glass-based article by a loading ring 430 having a diameter D1.

The ratio of diameters of the loading ring and support ring D1/D2 may be in a range from 0.2 to 0.5. In some embodiments, D1/D2 is 0.5. Loading and support rings 130, 120 should be aligned concentrically to within 0.5% of support ring diameter D2. The load cell used for testing should be accurate to within ±1% at any load within a selected range. Testing is carried out at a temperature of 23±2° C. and a relative humidity of 40±10%.

For fixture design, the radius r of the protruding surface of the loading ring 430 is in a range of h/2 ≦r ≦3h/2, where his the thickness of glass-based article 410. Loading and support rings 430, 420 are made of hardened steel with hardness HRc >40. AROR fixtures are commercially available.

The intended failure mechanism for the AROR test is to observe fracture of the glass-based article 410 originating from the surface 430a within the loading ring 430. Failures that occur outside of this region—i.e., between the loading ring 430 and support ring 420—are omitted from data analysis. Due to the thinness and high strength of the glass-based article 410, however, large deflections that exceed ½ of the specimen thickness h are sometimes observed. It is therefore not uncommon to observe a high percentage of failures originating from underneath the loading ring 430. Stress cannot be accurately calculated without knowledge of stress development both inside and under the ring (collected via strain gauge analysis) and the origin of failure in each specimen. AROR testing therefore focuses on peak load at failure as the measured response.

The strength of glass-based article depends on the presence of surface flaws. However, the likelihood of a flaw of a given size being present cannot be precisely predicted, as the strength of glass is statistical in nature. A probability distribution can therefore in some cases be used as a statistical representation of the data obtained.

In embodiments, a glass article having a thickness of greater than or equal to about 0.8 mm has an abrasion resistance greater than or equal to about 35 kgf, such as greater than or equal to about 37 kgf. In other embodiments, a glass article having a thickness of greater than or equal to about 0.8 mm has an abrasion resistance greater than or equal to about 39 kgf, such as greater than or equal to about 40 kgf. In embodiments, a glass article having a thickness of less than or equal to about 0.55 mm has an abrasion resistance greater than or equal to about 15 kgf, such as greater than or equal to about 17 kgf. In other embodiments, a glass article having a thickness of less than or equal to about 0.55 mm has an abrasion resistance greater than or equal to about 18 kgf, such as greater than or equal to about 19 kgf

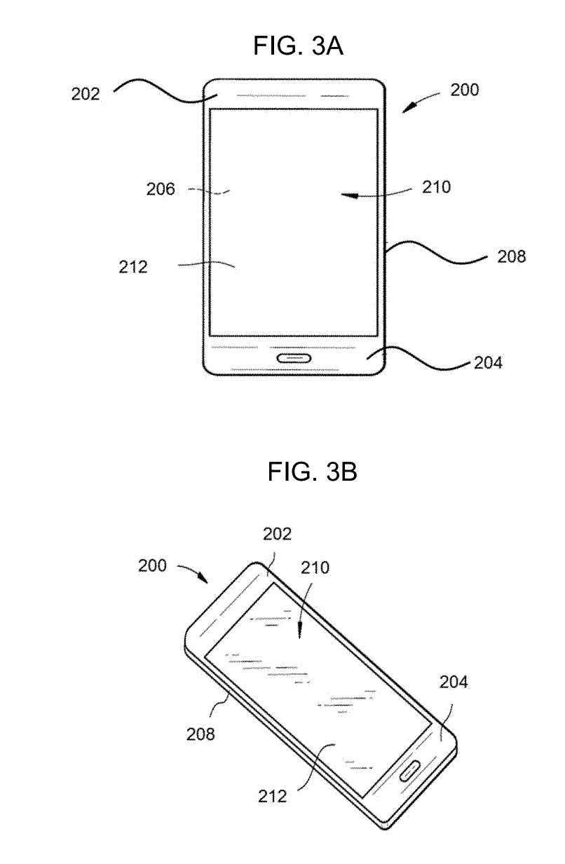

The strengthened glass articles disclosed herein may be incorporated into another article such as an article with a display (or display articles) (e.g., consumer electronics, including mobile phones, tablets, computers, navigation systems, and the like), architectural articles, transportation articles (e.g., automotive, trains, aircraft, sea craft, etc.), appliance articles, or any article that requires some transparency, scratch-resistance, abrasion resistance or a combination thereof. An exemplary article incorporating any of the strengthened articles disclosed herein is shown in FIGS. 3A and 3B. Specifically, FIGS. 3A and 3B show a consumer electronic device 200 including a housing 202 having front 204, back 206, and side surfaces 208; electrical components (not shown) that are at least partially inside or entirely within the housing and including at least a controller, a memory, and a display 210 at or adjacent to the front surface of the housing; and a cover substrate 212 at or over the front surface of the housing such that it is over the display. In some embodiments, the cover substrate 212 or housing 202 may include any of the strengthened glass articles disclosed herein.

### EXAMPLES

Embodiments of this disclosure will be further clarified by the following non-limiting examples.

Glass samples were prepared by blending and melting the following components: 65.38 mol. % SiO₂, 11.04 mol. % Al₂O₃, 9.69 mol. % Na₂O, 0.06 mol. % K₂O, 10.67 mol. % Li₂O, 0.46 mol. % MgO, 0.81 mol. % CaO, 1.80 mol. % ZrO₂, 0.02 mol. % TiO₂, 0.05 mol. % SrO, and 0.02 mol. % Fe₂O₃. Glass sheets having the thicknesses indicated in Table 1 were formed by a down-draw process. Once formed, the glass sheets were cut to the desired size and the cut edges were finished. The finished glass sheets were then submerged into a molten salt ion exchange bath having the composition shown in Table 1. The finished glass sheets were held in the ion exchange bath for the duration indicated in Table 1. Various samples were subsequently submerged in a second ion exchange bath having the concentration, duration, and temperature shown in Table 1. The strengthened glass sheets were then subjected to the abrasion resistance test described herein. The glass articles were also subjected to several drop tests as described above. The results of these tests are shown in Table 1.

TABLE 1

| | Comp. | Comp. | Comp. | | Comp. | |
|---|---|---|---|---|---|---|
| | Sample 1 | Sample 2 | Sample 3 | Sample 1 | Sample 4 | Sample 2 |
| Thickness | 0.8 | 0.8 | 0.8 | 0.8 | 0.55 | 0.55 |
| (mm) | | | | | | |
| First IOX | 2 | 6 | 7.2 | 6 | 2 | 6 |
| duration | | | | | | |
| (hrs) | | | | | | |
| First IOX | 390 | 390 | 390 | 390 | 390 | 390 |
| Temperature | | | | | | |
| (° C.) | | | | | | |
| First IOX | 100% | 95% | 63% | 70% | 100% | 70% |
| Bath | NaNO₃ | KNO₃/5% | KNO₃/37% | KNO₃/30% | NaNO₃ | KNO₃/30% |
| Composition | | NaNO₃ | NaNO₃ | NaNO₃ | | NaNO₃ |
| (mol. %) | | | | | | |
| Second IOX | 4 | NA | 0.2 | NA | 4 | NA |
| duration | | | | | | |
| (hrs) | | | | | | |
| Second IOX | 390 | NA | 390 | NA | 390 | NA |
| Temperature | | | | | | |
| (° C.) | | | | | | |
| Second IOX | 100% | NA | 100% | NA | 100% | NA |
| Bath | KNO₃ | | KNO₃ | | KNO₃ | |
| Composition | | | | | | |
| (mol. %) | | | | | | |
| Abrasion | 17 | 24 | 19 | 41 | 7 | 19 |
| Test (kgf) | | | | | | |
| Drop Test | | | | | | |
| Height 1 | 110 | 170 | 110 | >221 | 60 | >221 |
| (cm) | | | | | | |
| Height 2 | 120 | 120 | 140 | >221 | 90 | 140 |
| (cm) | | | | | | |
| Height 3 | 130 | 130 | 30 | >221 | 22 | >221 |
| (cm) | | | | | | |
| Height 4 | 130 | 170 | 80 | >221 | 90 | >221 |
| (cm) | | | | | | |
| Height 5 | 100 | 120 | 110 | >221 | 60 | >221 |
| (cm) | | | | | | |
| Height 6 | 130 | 170 | 120 | >221 | NA | 200 |
| (cm) | | | | | | |
| Height 7 | 220 | 210 | 90 | >221 | NA | >221 |
| (cm) | | | | | | |
| Height 8 | 130 | 120 | 70 | >221 | NA | 220 |
| (cm) | | | | | | |
| Height 9 | 180 | NA | 30 | >221 | NA | NA |
| (cm) | | | | | | |
| Avg. Height | 139 | 151 | 87 | >221 | 64 | 208 |
| (cm) | | | | | | |

In Table 1, “NA” indicates that the second ion exchange process or drop test was not conducted. Also, a “Height” below 221 cm of the drop test in Table 1 indicates the height at which the glass sheet failed by presenting a crack in the glass article after the drop test was conducted. For example, the glass sheet dropped as Sample 1, Height 1 failed by presenting a crack when the glass sheet was dropped at a height of 110 cm. However, 221 cm is the maximum height that a glass article can be dropped. Therefore, a drop test “Height” of “>221” in Table 1 indicates that the glass article did not crack at any tested height.

As shown in Table 1, Samples 1 and 2 that were ion exchanged in a single molten salt bath comprising 70 mol. % KNO₃ and 30 mol. % NaNO₃ performed better in both the drop test and the abrasion test than the comparative samples that were ion exchanged by a two-bath process (i.e., Comp. Samples 1, 3, and 4) or ion exchanged in a molten salt bath that comprised 95 mol. % KNO₃ and 5 mol. % NaNO₃ (i.e., Comp. Sample 2).

It will be apparent to those skilled in the art that various modifications and variations can be made to the embodiments described herein without departing from the spirit and scope of the claimed subject matter. Thus it is intended that the specification cover the modifications and variations of the various embodiments described herein provided such modification and variations come within the scope of the appended claims and their equivalents.

What is claimed is:

1. A method for strengthening a glass article comprising:
contacting a glass article with an ion exchange solution for a duration of from greater than or equal to about 4 hours to less than or equal to about 8 hours, the ion exchange solution having a temperature from greater than or equal to about 370° C. to less than or equal to about 410° C. during the contacting; and
separating the ion exchange solution from the glass article,
wherein:
the ion exchange solution comprises:
from greater than or equal to about 65 mol. % to less than or equal to about 75 mol. % KNO₃, and
from greater than or equal to about 25 mol. % to less than or equal to about 35 mol. % NaNO₃, and
prior to the contacting, the glass article comprises:
greater than or equal to about 55 mol. % to less than or equal to about 75 mol. % SiO₂,
greater than or equal to about 8 mol. % to less than or equal to about 15 mol. % Al₂O₃,
greater than or equal to about 5 mol. % to less than or equal to about 12 mol. % Na₂O,
greater than or equal to about 8 mol. % to less than or equal to about 14 mol. % Li₂O,
greater than or equal to 0 mol. % to less than or equal to about 1 mol. % K₂O,
greater than or equal to 0 mol. % to less than or equal to about 2 mol. % MgO,
greater than or equal to 0 mol. % to less than or equal to about 2 mol. % CaO, and
greater than or equal to 0 mol. % to less than or equal to about 2 mol. % ZrO₂.

2. The method for strengthening a glass article of claim 1, wherein a thickness of the glass article is less than or equal to about 1 mm.

3. The method for strengthening a glass article of claim 1, wherein a thickness of the glass article is from greater than or equal to about 0.45 mm to less than or equal to about 0.85 mm.

4. The method for strengthening a glass article of claim 1, wherein the duration of the contacting is from greater than or equal to about 5 hours to less than or equal to about 7 hours.

5. The method for strengthening a glass article of claim 1, wherein the ion exchange solution has a temperature from greater than or equal to about 380° C. to less than or equal to about 400° C. during the contacting.

6. The method for strengthening a glass article of claim 1, wherein the ion exchange solution comprises:
from greater than or equal to about 68 mol. % to less than or equal to about 72 mol. % KNO₃, and
from greater than or equal to about 28 mol. % to less than or equal to about 32 mol. % NaNO₃.

7. The method for strengthening a glass article of claim 1, wherein the ion exchange solution comprises about 70 mol. % KNO₃ and about 30 mol. % NaNO₃.

8. The method for strengthening a glass article of claim 1, wherein the glass article comprises:
greater than or equal to about 62 mol. % to less than or equal to about 68 mol. % SiO₂,
greater than or equal to about 10 mol. % to less than or equal to about 13 mol. % Al₂O₃,
greater than or equal to about 7 mol. % to less than or equal to about 10 mol. % Na₂O,
greater than or equal to about 9 mol. % to less than or equal to about 13 mol. % Li₂O,
greater than or equal to 0.01 mol. % to less than or equal to about 0.07 mol. % K₂O,
greater than or equal to 0.01 mol. % to less than or equal to about 0.5 mol. % MgO, and
greater than or equal to 0 mol. % to less than or equal to about 1 mol. % CaO.

9. A method for producing a strengthened glass article consisting essentially of:
contacting a glass article with an ion exchange solution for a duration of from greater than or equal to about 4 hours to less than or equal to about 8 hours, the ion exchange solution having a temperature from greater than or equal to about 370° C. to less than or equal to about 410° C. during the contacting; and
separating the ion exchange solution from the glass article,
wherein:
the ion exchange solution consists essentially of:
from greater than or equal to about 65 mol. % to less than or equal to about 75 mol. % KNO₃, and
from greater than or equal to about 25 mol. % to less than or equal to about 35 mol. % NaNO₃, and
prior to the contacting, the glass article consists essentially of:
greater than or equal to about 55 mol. % to less than or equal to about 75 mol. % SiO₂,
greater than or equal to about 8 mol. % to less than or equal to about 15 mol. % Al₂O₃,
greater than or equal to about 5 mol. % to less than or equal to about 12 mol. % Na₂O,
greater than or equal to about 8 mol. % to less than or equal to about 14 mol. % Li₂O,
greater than or equal to 0 mol. % to less than or equal to about 1 mol. % K₂O,
greater than or equal to 0 mol. % to less than or equal to about 2 mol. % MgO,
greater than or equal to 0 mol. % to less than or equal to about 2 mol. % CaO, and
greater than or equal to 0 mol. % to less than or equal to about 2 mol. % ZrO₂.

10. The method for producing a strengthened glass article of claim 9, wherein the ion exchange solution consists essentially of:
from greater than or equal to about 68 mol. % to less than or equal to about 72 mol. % KNO₃, and
from greater than or equal to about 28 mol. % to less than or equal to about 32 mol. % NaNO₃.

11. The method for producing a strengthened glass article of claim 9, wherein the glass article consists essentially of:
greater than or equal to about 62 mol. % to less than or equal to about 68 mol. % SiO₂,
greater than or equal to about 10 mol. % to less than or equal to about 13 mol. % Al₂O₃,
greater than or equal to about 7 mol. % to less than or equal to about 10 mol. % Na₂O,
greater than or equal to about 9 mol. % to less than or equal to about 13 mol. % Li₂O,
greater than or equal to 0.01 mol. % to less than or equal to about 0.07 mol. % K₂O,
greater than or equal to 0.01 mol. % to less than or equal to about 0.05 mol. % MgO, and
greater than or equal to 0.2 mol. % to less than or equal to about 1 mol. % CaO.

12. The method for producing a strengthened glass article of claim 9, wherein the ion exchange solution has a temperature from greater than or equal to about 380° C. to less than or equal to about 400° C. during the contacting.

13. A strengthened aluminosilicate glass article formed by a method comprising:
contacting a precursor glass article and an ion exchange solution for a duration of from greater than or equal to about 4 hours to less than or equal to about 8 hours, the ion exchange solution having a temperature from greater than or equal to about 370° C. to less than or equal to about 410° C. during the contacting; and
separating the ion exchange solution from the precursor glass article, yielding the strengthened aluminosilicate glass article,
wherein:
the ion exchange solution comprises:
from greater than or equal to about 65 mol. % to less than or equal to about 75 mol. % KNO₃, and
from greater than or equal to about 25 mol. % to less than or equal to about 35 mol. % NaNO₃,
the precursor glass article comprises:
greater than or equal to about 55 mol. % to less than or equal to about 75 mol. % SiO₂,
greater than or equal to about 8 mol. % to less than or equal to about 15 mol. % Al₂O₃,
greater than or equal to about 5 mol. % to less than or equal to about 12 mol. % Na₂O,
greater than or equal to about 8 mol. % to less than or equal to about 15 mol. % Li₂O,
greater than or equal to 0 mol. % to less than or equal to about 2 mol. % K₂O,
greater than or equal to 0 mol. % to less than or equal to about 2 mol. % MgO,
greater than or equal to 0 mol. % to less than or equal to about 2 mol. % CaO, and
greater than or equal to 0 mol. % to less than or equal to about 2 mol. % ZrO₂, and
the strengthened aluminosilicate glass article survives a drop test from a height of greater than or equal to about 190 cm.

14. The strengthened aluminosilicate glass article of claim 13, wherein the precursor glass article comprises:
greater than or equal to about 62 mol. % to less than or equal to about 68 mol. % SiO₂,
greater than or equal to about 10 mol. % to less than or equal to about 13 mol. % Al₂O₃,
greater than or equal to about 7 mol. % to less than or equal to about 11 mol. % Na₂O,
greater than or equal to about 9 mol. % to less than or equal to about 12 mol. % Li₂O,
greater than or equal to 0 mol. % to less than or equal to about 1 mol. % K₂O,
greater than or equal to 0 mol. % to less than or equal to about 1 mol. % MgO, and
greater than or equal to 0 mol. % to less than or equal to about 1 mol. % CaO.

15. The strengthened aluminosilicate glass article of claim 13, wherein the strengthened aluminosilicate glass article survives a drop test from a height of greater than or equal to about 200 cm.

16. The strengthened aluminosilicate glass article of claim 13, wherein the strengthened aluminosilicate glass article survives a drop test from a height of greater than or equal to about 220 cm.

17. The strengthened aluminosilicate glass article of claim 13, wherein the strengthened aluminosilicate glass article has a thickness less than or equal to about 0.8 mm, and an abrasion resistance of greater than or equal to about 35 kgf.

18. The strengthened aluminosilicate glass article of claim 13, wherein the strengthened aluminosilicate glass article has a thickness less than or equal to about 0.55 mm, and an abrasion resistance of greater than or equal to about 15 kgf.

19. The strengthened aluminosilicate glass article of claim 13, wherein the ion exchange solution comprises:
from greater than or equal to about 68 mol. % to less than or equal to about 72 mol. % KNO₃, and
from greater than or equal to about 28 mol. % to less than or equal to about 32 mol. % NaNO₃.

20. The strengthened aluminosilicate glass article of claim 13, wherein the ion exchange solution has a temperature from greater than or equal to about 380° C. to less than or equal to about 400° C. during the contacting.

21. A consumer electronic product, comprising:
a housing having a front surface, a back surface and side surfaces;
electrical components provided at least partially within the housing, the electrical components including at least a controller, a memory, and a display, the display being provided at or adjacent the front surface of the housing; and
a cover glass disposed over the display,
wherein at least one of a portion of the housing or the cover glass comprises the strengthened aluminosilicate glass article of claim 13.
